(19) United States
(12) Patent Application Publication
(10) Pub. No.: US 2026/0190510 A1
(43) Pub. Date: Jul. 2, 2026

(54) METHOD OF MANUFACTURING A SEMICONDUCTOR PACKAGE

(71) Applicant: Samsung Electronics Co., Ltd., Suwon-si (KR)

(72) Inventor: Jesung Kim, Suwon-si (KR)

(21) Appl. No.: 19/386,934

(22) Filed: Nov. 12, 2025

(30) Foreign Application Priority Data
Dec. 26, 2024 (KR) 10-2024-0197322

(51) Int. Cl. H10F 39/00

(52) U.S. Cl. CPC H10F 39/026; H10F 39/804; H10F 39/811

(57) ABSTRACT

In a method of manufacturing a semiconductor package, a first portion of a wafer may be partially removed by performing a blade sawing process to form a first opening. The wafer may include an active surface and an inactive surface opposite to each other in a vertical direction, and the first portion may be adjacent to the inactive surface of the wafer. A second portion of the wafer overlapping the first opening in the vertical direction may be removed by performing a laser grooving process through the first opening to singulate the wafer into a plurality of chips. One of the plurality of chips may be mounted on a package substrate.

### CROSS-REFERENCE TO RELATED APPLICATION

This application claims priority under 35 USC § 119 to Korean Patent Application No. 10-2024-0197322, filed on Dec. 26, 2024 in the Korean Intellectual Property Office (KIPO), the contents of which are herein incorporated by reference in their entirety.

### BACKGROUND

### 1. Field

Example embodiments relate to a method of manufacturing a semiconductor package. More particularly, example embodiments relate to a method of manufacturing a semiconductor package including an image sensor chip.

### 2. Description of the Related Art

An image sensor chip is manufactured by performing a sawing process on a wafer, and during the sawing process, particles are generated to attach to the image sensor chip so as to cause defects in the image sensor chip.

### SUMMARY

Example embodiments provide a method of manufacturing a semiconductor package having improved characteristics.

According to example embodiments, there is provided a method of manufacturing a semiconductor package. In the method, a first portion of a wafer may be partially removed by performing a blade sawing process to form a first opening. The wafer may include an active surface and an inactive surface opposite to each other in a vertical direction, and the first portion may be adjacent to the inactive surface of the wafer. A second portion of the wafer overlapping the first opening in the vertical direction may be removed by performing a laser grooving process through the first opening to singulate the wafer into a plurality of chips. One of the plurality of chips may be mounted on a package substrate.

According to example embodiments, there is provided a method of manufacturing a semiconductor package. In the method, a first portion of a wafer may be partially removed by performing a blade sawing process to form a first opening. The wafer may include an active surface and an inactive surface opposite to each other in a vertical direction. The first portion may be adjacent to the inactive surface of the wafer. First particles of a first material included in the first portion may attach to the inactive surface of the wafer during the blade sawing process. At least some of the first particles may be removed by performing a first cleaning process on the wafer using deionized water (DIW). A protective layer may be formed on the inactive surface of the wafer and sidewalls and lower surfaces of the first opening. A portion of the protective layer and a second portion of the wafer overlapping the first opening in the vertical direction may be removed by performing a laser grooving process through the first opening to form a second opening connected to the first opening. Second particles of a second material included in the second portion may be attached to the protective layer during the laser grooving process. At least some of the second particles may be removed by performing a cleaning process on the wafer using deionized water (DIW).

According to example embodiments, there is provided a method of manufacturing a semiconductor package. In the method, a first portion of a wafer may be partially removed by performing a blade sawing process to form a first opening. The wafer may include an active surface and an inactive surface opposite to each other in a vertical direction. A protective layer may be formed on the inactive surface of the wafer and sidewalls and lower surfaces of the first opening. A portion of the protective layer and a second portion of the wafer overlapping the first opening in the vertical direction may be removed by performing a laser grooving process through the first opening to singulate the wafer into a plurality of chips. Each of the plurality of chips may be mounted on a package substrate. A wire bonding process may be performed to electrically connect chip pads included in the plurality of chips to substrate pads, respectively, included in the package substrate. A cover glass may be disposed on one of the plurality of chips. A molding member may be formed on the package substrate to cover sidewalls of the plurality of chips and a lower sidewall of the cover glass.

In the method of manufacturing the semiconductor package in accordance with example embodiments, the singulation process for cutting the wafer into a plurality of image sensor chips may be performed on the inactive surface of the wafer after flipping the wafer. Even if the particles generated during the singulation process are not entirely removed but may remain, the particles may remain only on the inactive surface of the image sensor chip, so that defects may not be generated in the image sensor chip.

### BRIEF DESCRIPTION OF THE DRAWINGS

FIGS. 1 to 19 are plan views and cross-sectional views illustrating a method of manufacturing a semiconductor package in accordance with example embodiments.

### DESCRIPTION OF EMBODIMENTS

Example embodiments will be more clearly understood from the following detailed description taken in conjunction with the accompanying drawings. It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

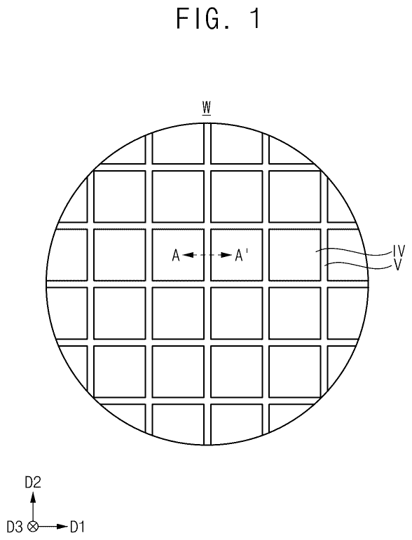

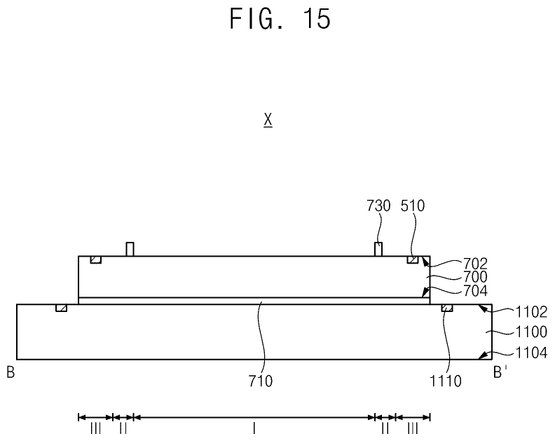

FIGS. 1 to 19 are plan views and cross-sectional views illustrating a method of manufacturing a semiconductor package in accordance with example embodiments.

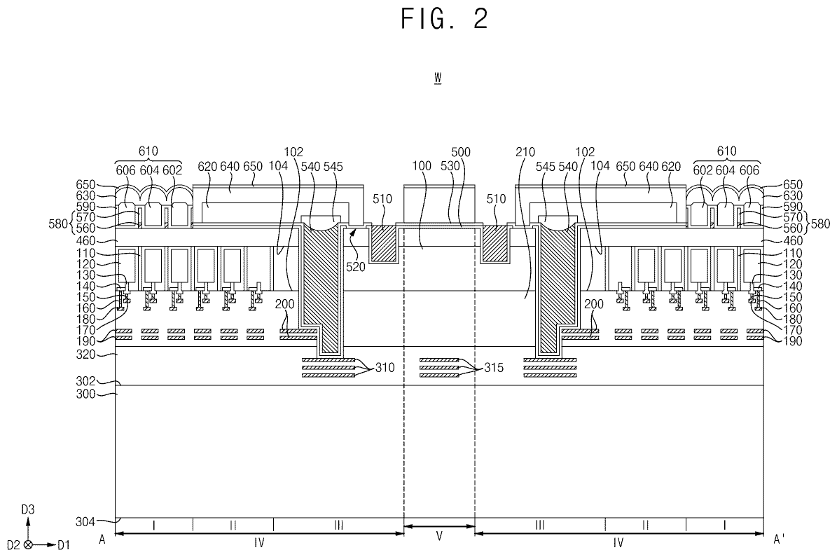

Particularly, FIGS. 1, 3, 12, 14 and 16 are the plan views, and FIGS. 2, 4-11, 13, 15 and 17-19 are the cross-sectional views. FIGS. 2 and 4-11 are cross-sectional views taken along lines A-A′ of corresponding plan views, respectively, and FIGS. 13, 15 and 17-19 are cross-sectional views taken along lines B-B′ of corresponding plan views, respectively.

In FIGS. 1 to 11, two directions crossing each other among horizontal directions that are substantially parallel to an upper surface of a wafer or a substrate may be referred to as first and second directions D1 and D2, respectively, and a vertical direction substantially perpendicular to the upper surface of the wafer or the substrate may be referred to as a third direction D3. In example embodiments, the first and second directions D1 and D2 may be substantially perpendicular to each other.

Referring to FIGS. 1 and 2, a wafer W including a plurality of image sensors may be provided.

The wafer W may include fourth regions IV, and a fifth region V surrounding each of the fourth regions IV. In example embodiments, each of the fourth regions IV may have a shape of, e.g., a rectangle or a square in a plan view, and the fourth regions IV may be arranged in a lattice pattern. Each of the fourth regions IV may be a die region, and the fifth region V may be a scribe lane region.

In example embodiments, each of the fourth regions IV may include first to third regions I, II and III. In a plan view, the first region I may have a shape of a rectangle or a square, the second region II may surround the first region I, and the third region III may surround the second region II, however, the inventive concept is not limited thereto.

In example embodiments, the first region I may be an active pixel region in which active pixels are disposed, the second region II may be an optical black (OB) region in which OB pixels are disposed or a non-active pixel sensor (non-APS) region, and the third region III may be a pad region or a peripheral circuit region in which a chip pad and/or a through via are disposed.

Each of the first to fifth regions I, II, III, IV and V may include not only a corresponding portion of a wafer, a panel or a substrate but also a corresponding space over and under the wafer, the panel or the substrate.

Each of the image sensors may include a second substrate 300, a second insulating interlayer 320, a first insulating interlayer 210, a first substrate 100 and a lower planarization layer 460 sequentially stacked in the third direction D3 in the first to third regions I, II and III. A color filter array layer 610, a microlens 630 and a transparent protective layer 650 may be sequentially stacked on the lower planarization layer 460 in the first region I. A light blocking layer 620, an upper planarization layer 640 and the transparent protective layer 650 may be sequentially stacked on the lower planarization layer 460 in the second region II and a portion of the third region III. The upper planarization layer 640 and the transparent protective layer 650 may be stacked on the lower planarization layer 460 in a portion of the third region III.

The image sensor may further include first to third wirings 170, 180 and 190 and first and second vias 150 and 160 disposed in the first insulating interlayer 210, a pixel division pattern 110 extending through the first substrate 100 in the third direction D3, a light sensing element 120 in each of unit pixel regions that may be defined by the pixel division pattern 110, a transfer gate (TG) 130 extending through a lower portion of the first substrate 100 and including a lower portion that may protrude under a first surface 102 of the first substrate 100 and by covered by the first insulating interlayer 210, and a floating diffusion (FD) region 140 at the lower portion of the first substrate 100 adjacent to the TG 130, in the first and second regions I and II.

The imager sensor may further include an interference blocking structure 580 disposed between first to third color filters 602, 604 and 606 included in the color filter array layer 610, and a first protective layer 590 covering a surface of the interference blocking structure 580 on the lower planarization layer 460, in the first region I.

The imager sensor may further include a fourth wiring 200 disposed in the first insulating interlayer 210, a fifth wiring 310 disposed in the second insulating interlayer 320, and a through via structure extending through the lower planarization layer 460, the first substrate 100, the first insulating interlayer 210 and an upper portion of the second insulating interlayer 320 to contact the fourth and fifth wirings 200 and 310, in the third region III.

The imager sensor may further include a sixth wiring 315 disposed in the second insulating interlayer 320, and a chip pad 510 extending through the lower planarization layer 460 and an upper portion of the first substrate 100, in the fourth region IV. The sixth wiring 315 may include, e.g., a test element group (TEG), an overlay key, etc.

The imager sensor may further include transistors on the first surface 102 of the first substrate 100. The transistors may include, e.g., a source follower transistor, a reset transistor and a select transistor. The TG 130 and the FD region 140 may collectively form a transfer transistor. The light sensing element 120 may serve as a source region of the transfer transistor, and the FD region 140 may serve as a drain region of the transfer transistor.

The first substrate 100 may include the first surface 102 and a second surface 104 opposite to the first surface 102, and the second substrate 300 may include a first surface 302 and a second surface 304 opposite to the first surface 302 thereof. FIG. 2 shows that the first surface 102 of the first substrate 100 is disposed under the second surface 104 thereof, and the first surface 302 of the second substrate 300 is disposed over the second surface 304 thereof.

In example embodiments, p-type impurities may be doped into a portion or an entire portion of the first substrate 100, and a p-type well may be formed in the first substrate 100.

The pixel division pattern 110 may extend in the third direction D3 in the first and second regions I and II of the first substrate 100, and may have a lattice pattern arranged in the first and second regions I and II, in a plan view. A plurality of unit pixel regions that may be defined by the pixel division pattern 110 may be arranged in each of the first and second directions D1 and D2.

In example embodiments, the light sensing element 120 may be a photodiode (PD). The light sensing element 120 may be an n-type impurity region doped with n-type impurities in the p-type well in the first and second regions I and II of the first substrate 100, and thus the light sensing element 120 and the p-type well may collectively form a PN junction diode. In an example embodiment, a p-type impurity region highly doped with p-type impurities at a portion of the first substrate 100 adjacent to the pixel division pattern 110 may be further formed, so that the PN junction diode may have enhanced electric characteristics.

The light sensing element 120 may be disposed in each unit pixel region defined by the pixel division pattern 110 in the first and second regions I and II of the first substrate 100, however, the light sensing element 120 may not be disposed in some of the unit pixel regions defined by the pixel division pattern 110 in the second region II of the first substrate 100.

The TG 130 may include a buried portion extending in the third direction D3 upwardly from the first surface 102 of the first substrate 100 and a protruding portion beneath the buried portion and having a lower surface lower than the first surface 102 of the first substrate 100.

The FD region 140 may be disposed at a portion of the first substrate 100 adjacent to the first surface 102 of the first substrate 100 and the TG 130, and may be an impurity region doped with, e.g., n-type impurities.

The first via 150 may contact the TG 130, and may be electrically connected to the first wiring 170. The second via 160 may contact the FD region 140, and may be electrically connected to the second wiring 180.

Vias and wirings electrically connected to the transistors, e.g., the source follower transistors, the reset transistors and the select transistors may be further formed in the first insulating interlayer 210, in the first and second regions I and II. FIG. 2 shows that the third wirings 190 are disposed at two levels in the third direction D3 and the fourth wirings 200 are disposed at two levels in the third direction D3, however, the inventive concept may not be limited thereto.

Each of the first and second insulating interlayers 210 and 320 may include an oxide, e.g., silicon oxide, or a low-k dielectric material.

In an example embodiment, the lower planarization layer 460 may include first to fifth layers sequentially stacked in the third direction D3. For example, the first to fifth layers may include, e.g., aluminum oxide, hafnium oxide, silicon oxide, silicon nitride and hafnium oxide, respectively.

The interference blocking structure 580 may be disposed on the lower planarization layer 460, and may overlap the pixel division pattern 110 in the third direction D3. The interference blocking structure 580 may have a shape of a lattice in a plan view. In example embodiments, the interference blocking structure 580 may include a first interference blocking pattern 560 and a second interference blocking pattern 570 sequentially stacked in the third direction D3. The first interference blocking pattern 560 may include a metal having a low light absorption rate, e.g., tungsten, and the second interference blocking pattern 570 may include a low refractive index material (LRIM), e.g., silicon oxide. Alternatively, the interference blocking structure 580 may have a single layer structure including a transparent LRIM.

The first protective layer 590 may include a metal oxide, e.g., aluminum oxide. The color filter array layer 610 may be disposed on the first protective layer 590, and may include, e.g., the first to third color filters 602, 604 and 606. Thus, a lower surface and a sidewall of each of the first to third color filters 602, 604 and 606 included in the color filter array layer 610 may be covered by the first protective layer 590.

The light blocking structure 620 may include a material substantially the same as that of the second color filter 604 that may absorb light in a relatively longer wavelength range and transmit light in a relatively shorter wavelength range among the first to third color filters 602, 604 and 606.

The light blocking structure 620 may be disposed on the lower planarization layer 460, the through via structure and an insulation pattern 530 in the second and third regions II and III, however, the light blocking structure 620 may not be disposed on a portion of the insulation pattern 530 on a trench 520 that may be formed by removing a conductive pattern 500 on the lower planarization layer 460 in a portion of the third region III and may expose an upper surface of the lower planarization layer 460.

The through via structure may include a filling pattern 540 extending in the third direction D3 through the lower planarization layer 460, the first substrate 100, the first insulating interlayer 210 and the upper portion of the second insulating interlayer 320, the insulation pattern 530 covering a sidewall and a lower surface of the filling pattern 540, the conductive pattern 500 covering a sidewall and a lower surface of the insulation pattern 530, and a capping pattern 545 on an upper surface of the filling pattern 540.

The filling pattern 540 may include, e.g., a LRIM, and the capping pattern 545 may include, e.g., a photoresist material.

A portion of the conductive pattern 500 included in the through via structure may contact the fourth and fifth wirings 200 and 310, and may electrically connect the fourth and fifth wirings 200 and 310 to each other. The conductive pattern 500 may be included in the through via structure, and may also be disposed on the lower planarization layer 460 in the second to fourth regions II, III and IV.

The conductive pattern 500 may include a metal, e.g., tungsten. In an example embodiment, a barrier pattern including a metal nitride, e.g., titanium nitride may be disposed under the conductive pattern 500.

The insulation pattern 530 may be included in the through via structure, and may also be disposed on a portion of the conductive pattern 500 on the lower planarization layer 460 in the second to fourth regions II, III and IV. The insulation pattern 530 may include an oxide, e.g., silicon oxide.

The chip pad 510 may be electrically connected to an outside wiring, and may be a path for electrical signals from/to the active pixel and/or the OB pixel to/from the outside wiring. The chip pad 510 may include a metal, e.g., aluminum. A sidewall and a lower surface of the chip pad 510 may be covered by the conductive pattern 500.

The microlens 630 may be disposed on the color filter array layer 610 and the first protective layer 590 in the first region I. The upper planarization layer 640 may be disposed on the light blocking structure (or light blocking layer) 620 and the insulation pattern 530 in the second to fourth regions II, III and IV, however, may not cover an upper surface of the chip pad 510 in the third region III. In example embodiments, the microlens 630 and the upper planarization layer 640 may include substantially the same material, e.g., a photoresist material having a high transparency.

The transparent protective layer 650 may be disposed on the microlens 630 and the upper planarization layer 640. The transparent protective layer 650 may include, e.g., indium tin oxide (ITO), indium zinc oxide (IZO), etc.

In the wafer W including the plurality of image sensors, the second surface 304 of the second substrate 300 may be an inactive surface, and a surface of the wafer W opposite the second surface 304 of the second substrate 300, for example, an upper surface of the transparent protective layer 650 on the microlens 630 and the upper planarization layer 640 may be an active surface.

In some embodiments, the wafer W may include a plurality of semiconductor chips such as memory chips, logic chips and so on. In this case, patterns constituting circuitry may be formed on or adjacent to the active surface, but no pattern constituting circuitry is formed on or adjacent to the inactive surface. In other cases, more patterns constituting circuitry may be formed on or adjacent to the active surface than the inactive surface.

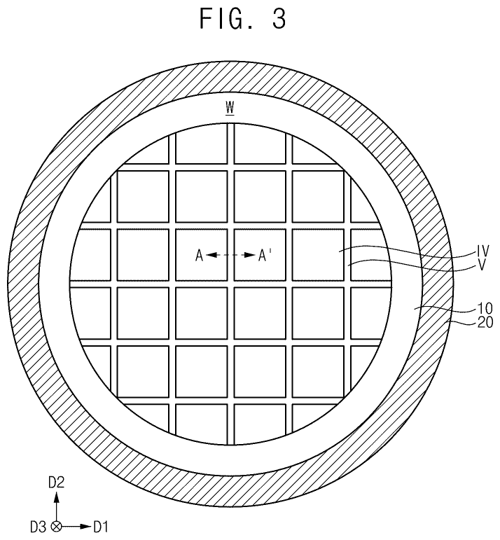

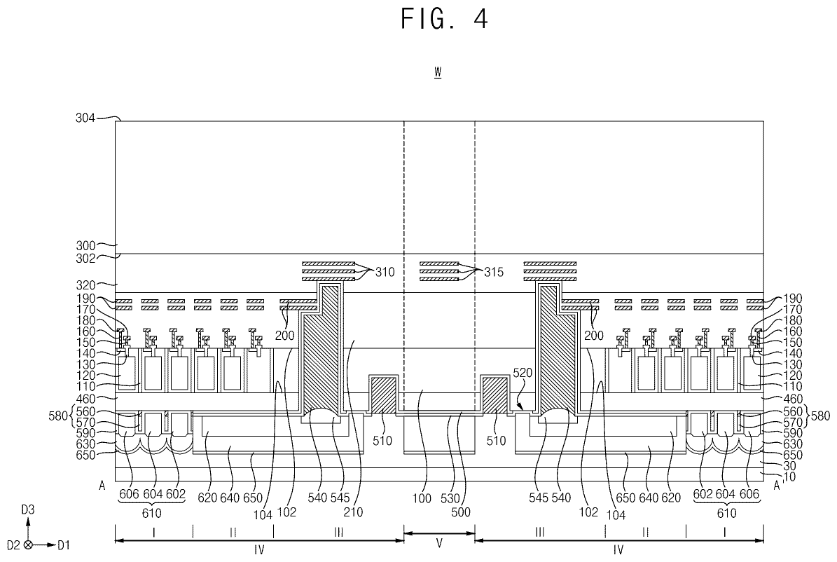

Referring to FIGS. 3 and 4, after flipping (e.g., turning over) the wafer W, the wafer may be mounted on a ring frame including a base structure (or a base plate) 10 and a border 20 through a temporary adhesion layer 30.

In example embodiments, the wafer W may be mounted on the ring frame such that the active surface of the wafer W1 may contact the temporary adhesion layer 30 and the inactive surface of the wafer W1, for example, the second surface 304 of the second substrate 300 may face upwardly.

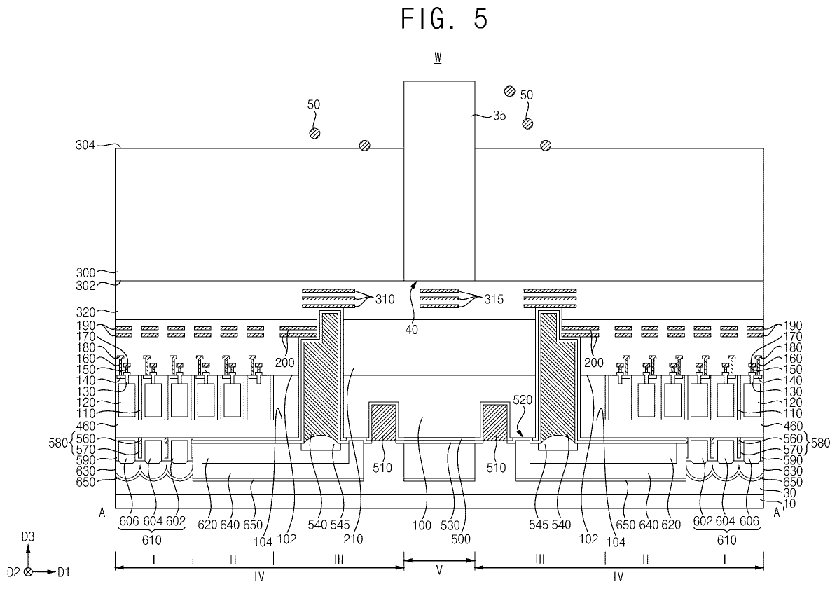

Referring to FIG. 5, a blade sawing process may be performed using a blade 35 to cut the second substrate 300 included in the wafer W. The blade sawing process may be a method of cutting a semiconductor wafer using, e.g., a rotating circular blade. For example, a high-speed rotating blade may be used to cut along the predefined scribe lane region (fifth region V), thereby separating the wafer into individual semiconductor chips (dies). In an embodiment, the blade may be made of a diamond-coated material to ensure precision and minimize damage to the chips.

As the blade sawing process is performed, a first opening 40 may be formed through the second substrate 300 to expose an upper surface of the second insulating interlayer 320.

During the blade sawing process, first particles 50 may be emitted over (or generated onto) the wafer W from the second substrate 300, and some of the first particles 50 may be attached to the second surface 304 of the second substrate 300. In example embodiments, each of the first particles 50 may include a semiconductor material included in the second substrate 300, e.g., silicon.

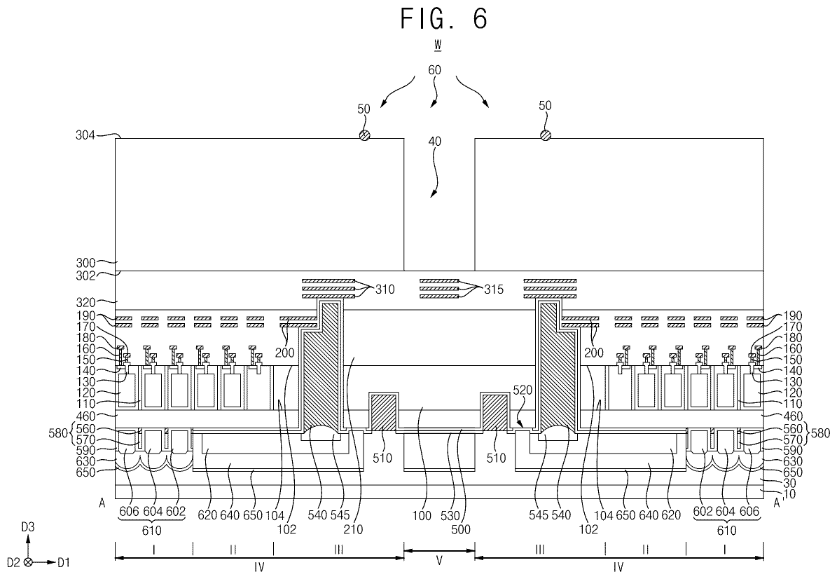

Referring to FIG. 6, the blade 35 may be removed from the wafer W, and a first cleaning process may be performed on the wafer W using, e.g., deionized wafer (DIW) 60.

Thus, most of the first particles 50 emitted over the wafer W may be removed, however, some of the first particles 50 attached to the second surface 304 of the second substrate 300 may not be removed but remain.

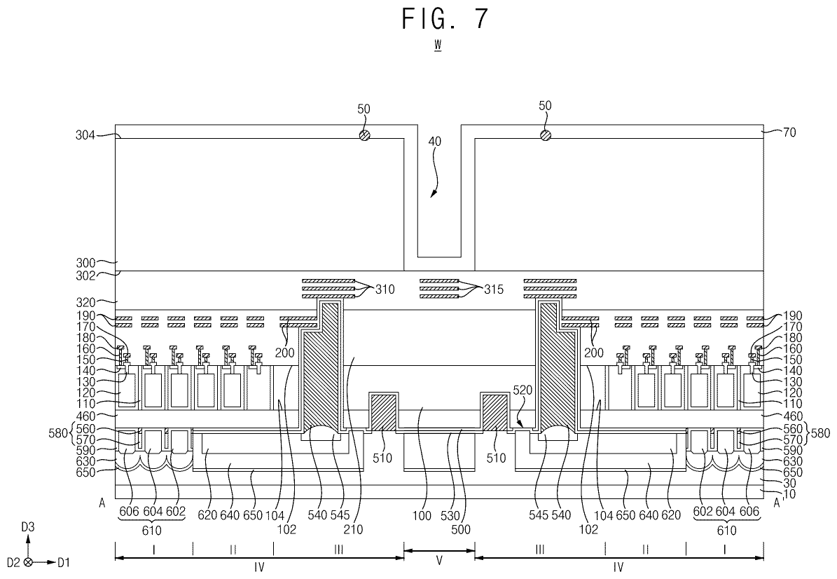

Referring to FIG. 7, a second protective layer 70 may be coated on the second surface 304 of the second substrate 300 and a sidewall of the second substrate 300 and an upper surface of the second insulating interlayer 320 exposed by the first opening 40.

The second protective layer 70 may be formed by, e.g., a coating process, and may cover the first particles 50 remaining on the second surface 304 of the second substrate 300.

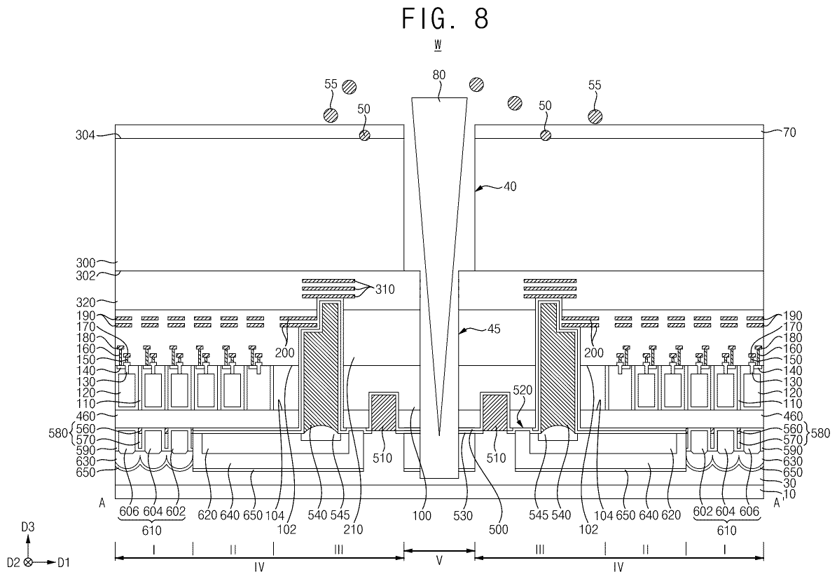

Referring to FIG. 8, a grooving process may be performed using a laser.

The grooving process may be performed by transmitting a laser beam 80 through the first opening 40 to the second protective layer 70 and the wafer W, and thus the second protective layer 70, the first and second insulating interlayers 210 and 320, the sixth wiring 315, the first substrate 100, the lower and upper planarization layers 460 and 640, the transparent protective layer 650 and a portion of the temporary adhesion layer 30 may be partially removed to form a second opening 45 connected to the first opening 40.

In example embodiments, a spot size of the laser beam 80 may be equal to or less than a width of the first opening 40, and thus a width of the second opening 45 that may be formed by the laser grooving process may be equal to or less than the width of the first opening 40.

The laser grooving process may be a method of forming a groove along the predefined scribe lane region (fifth region V), e.g., by irradiating the wafer surface with a focused laser beam. In this process, a high-energy laser beam may be used to remove or melt material along the scribe lane region. By utilizing laser, a high-precision process to form narrow and/or shallow grooves may be achieved.

During the laser grooving process, second particles 55 may be emitted over the wafer W, and some of the second particles 55 may be attached to an upper surface of a portion of the second protective layer 70 on the second surface 304 of the second substrate 300 included in the wafer W. In example embodiments, each of the second particles 55 may include insulating materials included in the first and second insulating interlayers 210 and 320 and the lower and upper planarization layers 460 and 640, a conductive material included in the sixth wiring 315 and a semiconductor material, e.g., silicon included in the first substrate 100. In some embodiments, the material of second particles may be the same as or different from that of the first particles.

As the blade sawing process and the laser grooving process are performed, the wafer W1 may be singulated into a plurality of image sensor chips 700.

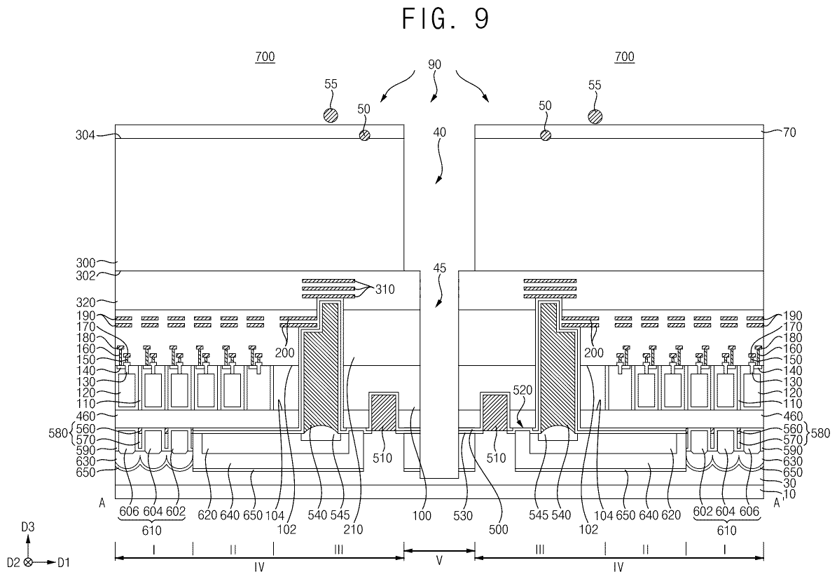

Referring to FIG. 9, a second cleaning process may be performed on the image sensor chips 700 using, e.g., DIW 90.

Thus, most of the second particles 55 emitted over the wafer W may be removed, however, some of the second particles 55 attached to the upper surface of the second protective layer 70 may not be removed but remain.

Referring to FIG. 10, after removing the second protective layer 70, the image sensor chips 700 and the temporary adhesion layer 30 may be separated from the base structure 10 and flipped.

The image sensor chips 700 and the temporary adhesion layer 30 may be mounted on the ring frame again such that the second surface 304 of the second substrate 300 included in each of the image sensor chips 700 may contact an upper surface of the base structure 10, and the temporary adhesion layer 30 may be removed.

When the temporary adhesion layer 30 is removed, the second particles 55 attached to the upper surface of the second protective layer 70 may also be removed, however, some of the first particles 50 covered by the second protective layer 70 may remain on the second surface 304 of the second substrate 300.

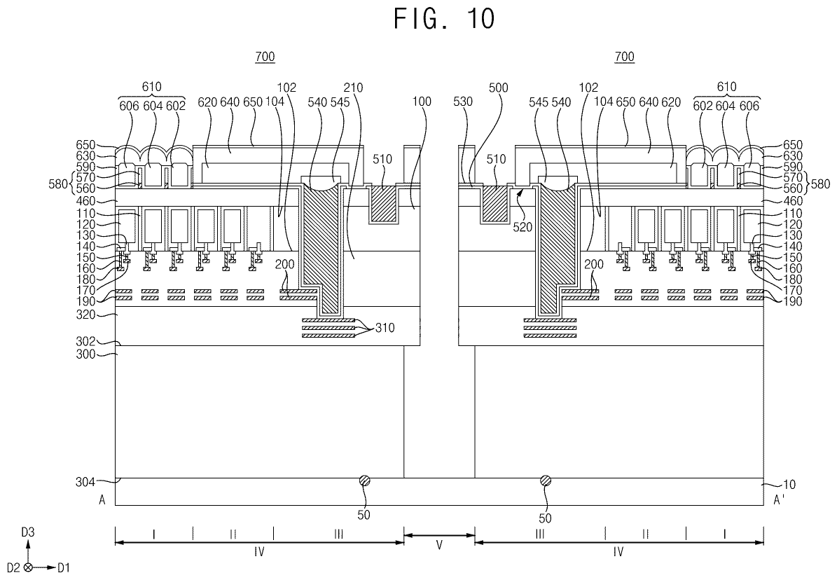

By the above processes, the image sensor chip 700 shown in FIG. 11 may be manufactured.

As illustrated above, the wafer W may be mounted on the ring frame such that the second surface 304 of the second substrate 300 (e.g., the inactive surface of the wafer W) may face upwardly, and the second substrate 300 may be cut by the blade sawing process. The first particles 50 emitted from the second substrate 300 may not be entirely removed by the first cleaning process but some of the first particles 50 may remain on the wafer W, however, the first particles 50 may remain only on the second surface 304 of the second substrate 300, which is the inactive surface.

The wafer W may be cut by the laser grooving process, and the second particles 55 emitted from the wafer W may be removed by the second cleaning process or during the removal of the second protective layer 70. Even if some of the first particles 50 attached to the second surface 304 of the second substrate 300 are not removed during the removal of the second protective layer 70, the second surface 304 of the second substrate 300 are the inactive surface, so that the first particles 50 remaining on the second surface 304 of the second substrate 300 may not affect the performance or operation of the image sensor chip 700.

If the laser grooving process and/or the blade sawing process are performed without flipping the wafer W, some of the first particles 50 and/or the second particles 55 emitted during the laser grooving process and/or the blade sawing process and not being removed by cleaning processes may be attached to the active surface of the image sensor chip 700 instead of the second surface 304 of the second substrate 300 (e.g., the inactive surface of the image sensor chip 700), and the performance or operation of the image sensor chip 700 may be deteriorated due to the first particles 50 and/or the second particles 55.

However, in example embodiments, the singulation process in which the wafer W is cut to be singulated into a plurality of image sensor chips 700 may be performed on the second surface 304 of the second substrate 300 after flipping the wafer W, and thus, even if some of the first particles 50 and/or the second particles 55 may not be removed but remain, which may remain only on the inactive surface of the image sensor chip 700 so as not to deteriorate the performance or operation of the image sensor chip 700.

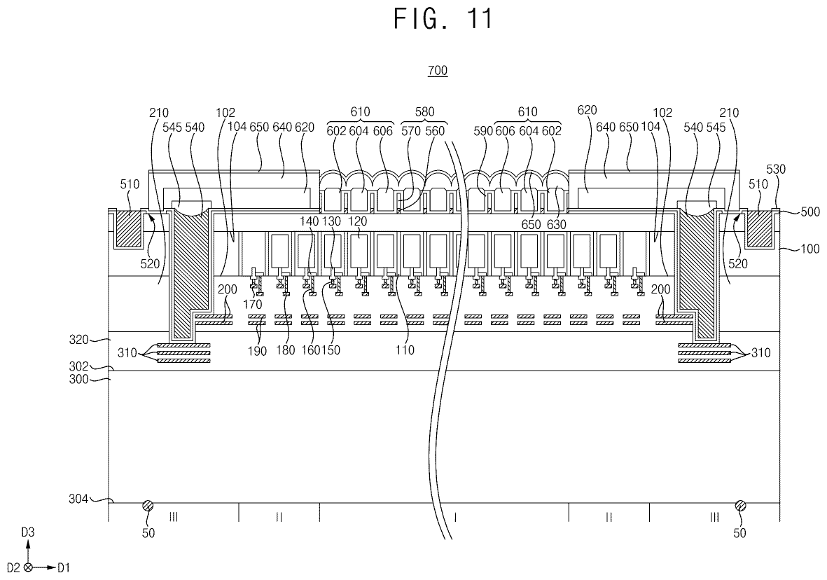

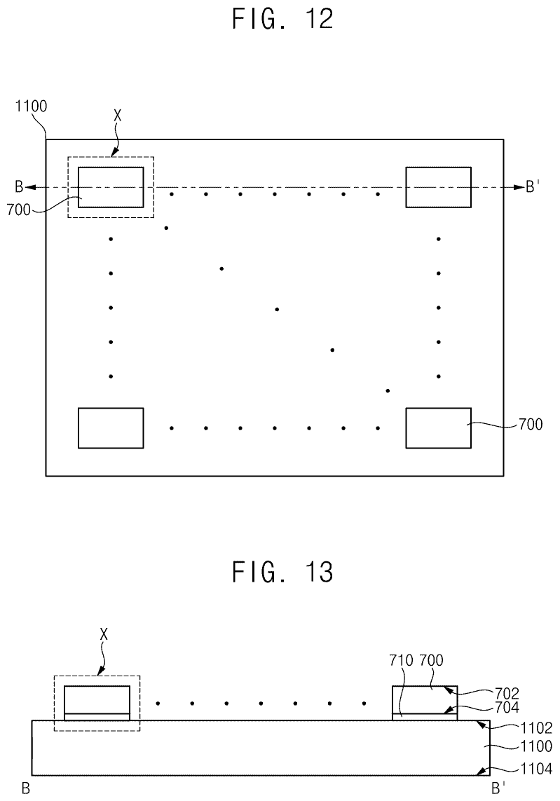

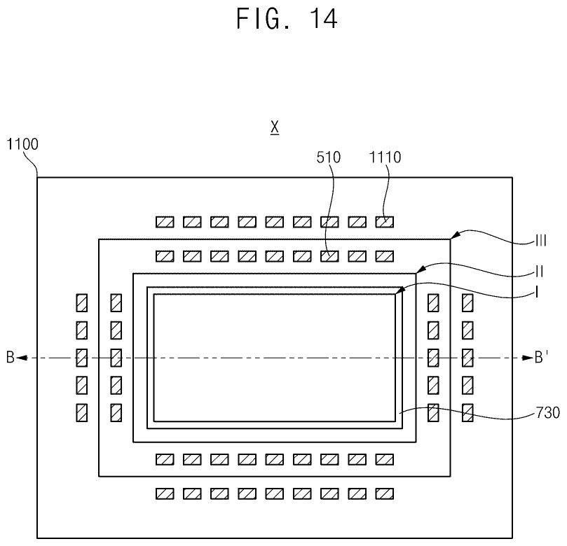

Referring to FIGS. 12 to 15, each of the image sensor chips 700 may be picked up from the ring frame, and may be mounted on a package substrate 1100. The image sensor chips 700 may be arranged on the package substrate 1100, e.g., in a regular array along two directions perpendicular each other. FIGS. 14 to 19 are plan views and cross-sectional views illustrating a portion (indicated by X in FIGS. 12 and 13) of a semiconductor package.

Hereinafter, in order to avoid the complexity of the drawings, other structures of the image sensor chip 700 except for the chip pad 510 may not be shown, and upper and lower surfaces of each of the image sensor chips 700 (e.g., first and second surfaces 702 and 704) are shown only. The second surface 704 of each of the image sensor chips 700 may correspond to the second surface 304 of the second substrate 300 in FIG. 11. Thus, the second surface 704 of the image sensor chip 700 may be an inactive surface, and the first surface 702 of the image sensor chip 700 may be an active surface.

In FIGS. 12 and 13, a plurality of image sensor chips 700 are illustrated to be formed on the package substrate 1100, but the invention is not limited thereto. For example, a single image sensor chip 700 may be formed on the package substrate 1100. In this regard, it will be readily understood by those skilled in the art that FIGS. 14 to 19 are plan views and cross-sectional views illustrating a portion of a semiconductor package, or alternatively, illustrating the entire semiconductor package.

The package substrate 1100 may include first and second surfaces 1102 and 1104 opposite to each other in a vertical direction, and may include a substrate pad 1110 adjacent to (or on) the first surface 1102 of the package substrate 1100.

A blocking structure 730 may be disposed in the second region II or the third region III in each of the image sensor chips 700. In example embodiments, the blocking structure 730 may have a shape of, e.g., a rectangular ring surrounding the first region I, in a plan view.

In example embodiments, a first adhesion layer 710 may be attached to the second surface 704 of each of the image sensor chips 700, and each of the image sensor chips 700 may be mounted on the first surface 1102 of the package substrate 1100 through the first adhesion layer 710.

In example embodiments, after each of the image sensor chips 700 is mounted on the first surface 1102 of the package substrate 1100 through the first adhesion layer 710, for example, a curing process may be performed on the first adhesion layer 710 so that each of the image sensor chips 700 may be bonded to the first surface 1102 of the package substrate 1100.

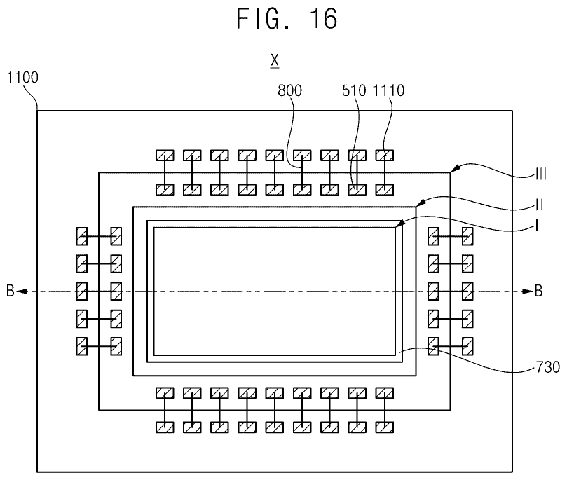

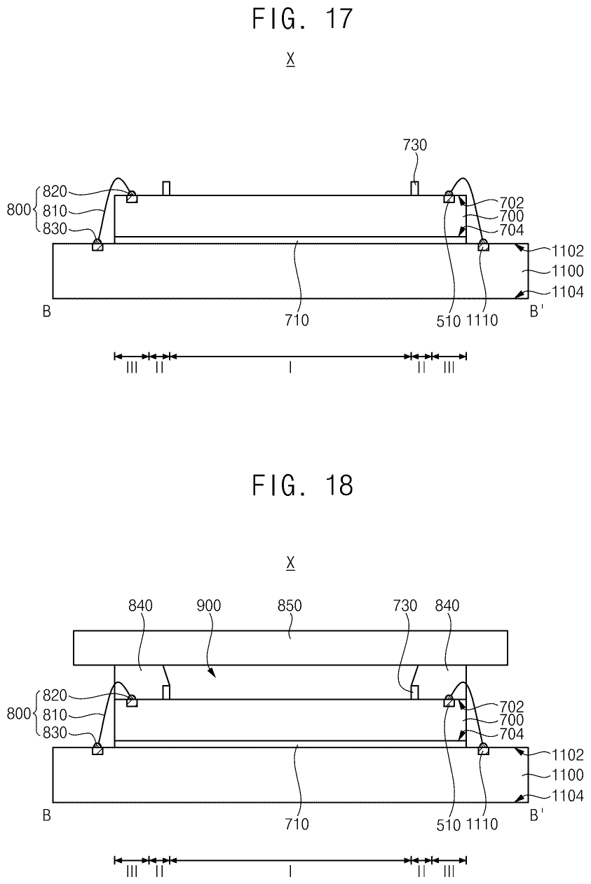

Referring to FIGS. 16 and 17, a wire bonding process may be performed to form a bonding wire 800 contacting the chip pad 510 of the image sensor chip 700 and the substrate pad 1110 of the package substrate 1100, so that the chip pad 510 and the substrate pad 1110 may be electrically connected to each other.

In example embodiments, a plurality of bonding wires 800 may be formed to contact the chip pads 510 and corresponding ones of the substrate pads 1110. Each of the bonding wires 800 may include a first contact portion 820 contacting an upper surface of the chip pad 510, a second contact portion 830 contacting an upper surface of the substrate pad 1110, and a vertical extension portion extending in the vertical direction to be connected to the first and second contact portions 820 and 830.

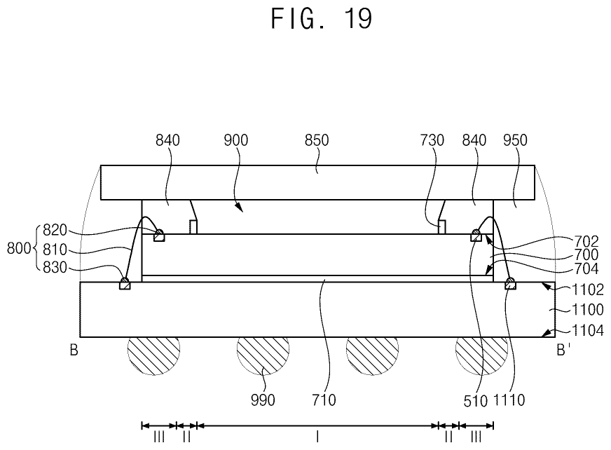

Referring to FIG. 18, a second adhesion layer 840 may be coated to cover the second and third regions II and III of the image sensor chip 700, a cover glass 850 may be mounted on the second adhesion layer 840, and a curing process may be performed on the second adhesion layer 840 so that the cover glass 850 may be bonded to the second adhesion layer 840.

When the cover glass 850 is bonded to the second adhesion layer 840, a space 900 may be formed between the image sensor chip 700 and the cover glass 850.

In example embodiments, the second adhesion layer 840 may be blocked (or confined) by the blocking structure 730 in the second region II of the image sensor chip 700, and thus may not be coated in an inside of the first region I. The second adhesion layer 840 may contact an outer sidewall of the blocking structure 730, and an upper surface of the second adhesion layer 840 may be higher than an upper surface of the blocking structure 730.

The second adhesion layer 840 may cover the chip pad 510 in the third region III of the image sensor chip 700, and the vertical extension portion 810 and the first contact portion 820 of the bonding wire 800.

In example embodiments, the cover glass 850 may have a shape of, e.g., a rectangular plate, and an area of the cover glass 850 may be greater than that of the image sensor chip 700.

Referring to FIG. 19, a molding member 950 may be formed on the first surface 1102 of the package substrate 1100, a conductive connection member 990 may be formed on the second surface 1104 of the package substrate 1100, and a singulation process may be performed on the package substrate 1100 and a structure on the package substrate 1100 to manufacture a plurality of semiconductor packages.

The molding member 950 may be disposed on the package substrate 1100, and may cover sidewalls of the first and second adhesion layers 710 and 840 and the image sensor chip 700, a lower sidewall of the cover glass 850 and the bonding wire 800.

By the above processes, the semiconductor package may be manufactured.

As described above, although the present invention has been described with reference to example embodiments, those skilled in the art will readily appreciate that many modifications are possible in the example embodiments without materially departing from the novel teachings and advantages of the present inventive concept.

What is claimed is:

1. A method of manufacturing a semiconductor package, the method comprising:
partially removing a first portion of a wafer by performing a blade sawing process to form a first opening, the wafer including an active surface and an inactive surface opposite to each other in a vertical direction, and the first portion being adjacent to the inactive surface of the wafer;
removing a second portion of the wafer overlapping the first opening in the vertical direction by performing a laser grooving process through the first opening to singulate the wafer into a plurality of chips; and
mounting one of the plurality of chips on a package substrate.

2. The method of claim 1, wherein the performing the laser grooving process through the first opening includes removing the second portion of the wafer overlapping the first opening in the vertical direction to form a second opening connected to the first opening and having a width smaller than that of the first opening.

3. The method of claim 1, further comprising, after performing the blade sawing process, performing a cleaning process on the wafer using deionized water (DIW).

4. The method of claim 1, further comprising, after performing the laser grooving process, performing a cleaning process on the wafer using deionized water (DIW).

5. The method of claim 1, further comprising, prior to performing the laser grooving process, forming a protective layer on the inactive surface of the wafer and a sidewall and a lower surface of the first opening.

6. The method of claim 5, wherein performing the laser grooving process includes removing a portion of the protective layer on the lower surface of the first opening.

7. The method of claim 5, wherein the second portion of the wafer includes an insulating material, a conductive material or a semiconductor material, and
wherein, while the laser grooving process is performed, particles including the insulating material, the conductive material or the semiconductor material attach to an upper surface of the protective layer.

8. The method of claim 1, further comprising, prior to the performing of the blade sawing process, mounting the wafer on a base plate through a temporary adhesion layer,
wherein, during the blade sawing process and the laser grooving process, the active surface of the wafer is bonded to the temporary adhesion layer, and the inactive surface of the wafer is disposed to face away from the base plate.

9. The method of claim 1, wherein the plurality of chips are image sensor chips.

10. The method of claim 1, further comprising, after mounting the one of the plurality of chips on the package substrate:
performing a wire bonding process to electrically connect chip pads included in the chip to substrate pads, respectively, included in the package substrate.

11. The method of claim 10, further comprising, after performing the wire bonding process:
disposing a cover glass on the chip.

12. A method of manufacturing a semiconductor package, the method comprising:
partially removing a first portion of a wafer by performing a blade sawing process to form a first opening, wherein the wafer includes an active surface and an inactive surface opposite to each other in a vertical direction, the first portion is adjacent to the inactive surface of the wafer, and first particles of a first material included in the first portion attach to the inactive surface of the wafer during the blade sawing process;
removing at least some of the first particles by performing a first cleaning process on the wafer using deionized water (DIW);
forming a protective layer on the inactive surface of the wafer and sidewall and lower surfaces of the first opening;
removing a portion of the protective layer and a second portion of the wafer overlapping the first opening in the vertical direction by performing a laser grooving process through the first opening to form a second opening connected to the first opening, wherein second particles of a second material included in the second portion are attached to the protective layer during the laser grooving process; and
removing at least some of the second particles by performing a second cleaning process on the wafer using deionized water (DIW).

13. The method of claim 12, wherein the first portion of the wafer includes a substrate including a semiconductor material.

14. The method of claim 12, wherein the second portion of the wafer includes an insulating interlayer including an insulating material and a wiring including a conductive material.

15. The method of claim 12, further comprising, prior to performing the blade sawing process, mounting the wafer on a base plate through a temporary adhesion layer,
wherein the active surface of the wafer is bonded to the temporary adhesion layer, and the inactive surface of the wafer is disposed to face away from the base plate.

16. A method of manufacturing a semiconductor package, the method comprising:
partially removing a first portion of a wafer by performing a blade sawing process to form a first opening, the wafer including an active surface and an inactive surface opposite to each other in a vertical direction;
forming a protective layer on the inactive surface of the wafer and a sidewall and a lower surface of the first opening;
removing a portion of the protective layer and a second portion of the wafer overlapping the first opening in the vertical direction by performing a laser grooving process through the first opening to singulate the wafer into a plurality of chips;
mounting each of the plurality of chips on a package substrate;
performing a wire bonding process to electrically connect chip pads included in the plurality of chips to substrate pads, respectively, included in the package substrate;
disposing a cover glass on one of the plurality of chips; and
forming a molding member on the package substrate to cover sidewalls of the plurality of chips and a lower sidewall of the cover glass.

17. The method of claim 16, wherein the first portion of the wafer includes a semiconductor material, and
wherein while the blade sawing process is performed, particles including the semiconductor material are attached to the inactive surface of the wafer.

18. The method of claim 17, further comprising, after performing the blade sawing process, performing a cleaning process on the wafer using deionized water (DIW) to remove at least some of the particles attached to the inactive surface of the wafer.

19. The method of claim 16, wherein the second portion of the wafer includes an insulating material, a conductive material or a semiconductor material, and
wherein while the laser grooving process is performed, particles including the insulating material, the conductive material or the semiconductor material attach to an upper surface of the protective layer.

20. The method of claim 19, further comprising, after the performing the laser grooving process, performing a cleaning process on the wafer using deionized water (DIW) to remove at least some of the particles attached to the upper surface of the protective layer.
